(19) United States
(12) Patent Application Publication
(10) Pub. No.: US 2002/0174397 A1
(43) Pub. Date: Nov. 21, 2002

(54) Method for error detection/correction of multilevel cell memory and multilevel cell memory having error detection/correction function

(75) Inventor: Hideyuki Furukawa, Kawasaki (JP)

Correspondence Address: ARENT FOX KINTNER PLOTKIN & KAHN, PLLC, Suite 600, 1050 Connecticut Avenue, N.W., Washington, DC, 20036-5339, US

(73) Assignee: FUJITSU LIMITED

(21) Appl. No.: 09/962,148

(22) Filed: Sep. 26, 2001

(30) Foreign Application Priority Data
May 16, 2001 (JP) 2001-146536

(51) Int. Cl. G11C 29/00

(52) U.S. Cl. 714/764

(57) ABSTRACT

Binary bit addresses for error detection designating the individual bits of multilevel memory cells for retaining two bits of data, respectively, are assigned so that pairs of the binary bit addresses corresponding to each of the memory cells are mutually exclusive in each digit. For each digit of the binary bit addresses, first parity codes including a parity code of data corresponding to all the binary bit addresses having “0” in the digit and a parity code of data corresponding to all the binary bit addresses having “1” in the digit are generated for both write data and read data. The presence of a memory cell storing erroneous data in both bits is detected when all the first parity codes of the read data are different from the first parity codes of the write data. Thus, the multilevel cell memory can perform reliable error detection/correction by a simple method.

### BACKGROUND OF THE INVENTION

1. Field of the Invention

The invention relates to a method for error detection/correction of a multilevel cell memory which can store a plurality of bits of information in each single memory cell.

2. Description of the Related Art

In general, semiconductor memories store a single bit of information in each single memory cell thereof. In writing and reading data, such semiconductor memories as a flash memory generate simple error correcting codes (ECCs) by access to their memory cells, and compare these ECCs to perform the detection/correcting of single-bit errors.

FIGS. 1 and 2 show a method for detecting/correcting a single-bit error in a flash memory. For simplicity, the following description deals with the case of accessing (writing/reading) memory cells in steps of eight bits. In actual flash memories, read operations and write operations are performed, for example, in steps of 4096 bits. In this embodiment, odd parity codes are used as ECCs.

In this example, binary bit addresses BA are used to generate parity codes. Binary bit addresses BA are binary representations of physical bit addresses PA which designate individual memory cells. Since eight memory cells are in question, a binary bit address BA is composed of three bits. Hereinafter, description will be given of the case where write data WD of “10010110” in binary is written to the memory cells, and read data RD of “10010010” in binary is read from the memory cells. That is, a data error occurs in the memory cell having a physical bit address PA of “2”.

As shown in FIG. 2, the number of bits of parity codes P0-P5 is set at six bits, or twice the number of bits of a binary bit address BA. The parity code P0 is calculated from the data corresponding to four binary bit addresses BA that have “0” in their least significant digits. That is, the parity code P0 is generated from the data to be written/read under four physical bit addresses “0”, “2”, “4”, and “6” corresponding to binary bit addresses “000”, “010”, “100”, and “110”.

The parity code P1 is calculated from the data corresponding to four binary bit addresses BA that have “1” in their least significant digits. That is, the parity code P1 is generated from the data to be written/read under four physical bit addresses “1”, “3”, “5”, and “7” corresponding to binary bit addresses “001”, “01 ”, “101”, and “111”.

Similarly, the parity codes P2 and P4 are calculated from the data corresponding to four binary bit addresses BA that have “0” in their second digits and third digits (most significant digits), respectively. The parity codes P3 and P5 are the parities of data corresponding to four binary bit addresses BA that have “1” in their second digits and third digits (most significant digits), respectively.

In this way, each bit of writing parity code WP and each bit of reading parity code RP are obtained from predetermined four bits of the write data WD (“10010110”) and predetermined four bits of the read data RD (“10010010”) shown in FIG. 1.

The parity codes P0-P5 are generated for situations where binary bit addresses BA have “0” or “1” in respective digits as described above. Therefore, when a single-bit error occurs, comparisons between the individual bits of the parity codes WP and RP indicate that either of the parity codes P0 and P1, either of the parity codes P2 and P3, and either of the parity codes P4 and P5 are inverted. Specifically, as shown in FIG. 2, the underlined error-occurring binary bit address BA (“010”) is included in either of the parity codes P0 and P1, in either of the parity codes P2 and P3, and in either of the parity codes P4 and P5. Therefore, if the exclusive ORs of the parities P0-P5 and the parities WP and RP (WP XOR RP) indicate differences between the parity codes P0 and P1, between the parity codes P2 and P3, and between the parity codes P4 and P5, then a single-bit error is detected. Here, the value of the error-occurring binary bit address BA is given by arranging the parity codes P5, P3, and P1 (“010” in this example). Then, the data read from this address is inverted for error correction.

Recently, the data amount to be handled in portable equipment with flash memory mounted, and the like has been on the increase, requiring flash memories of yet larger capacities. For this reason, there have been developed four-level cell flash memories which can store two bits of information in each single memory cell.

FIG. 3 shows the relationship between logical values of data and threshold voltage VTH in a flash memory that can store two bits of information in each single memory cell.

For example, when a memory cell has a threshold voltage VTH lower than the reference voltage V1, the data retained in the memory cell is “00”. When the threshold voltage VTH of a memory cell falls within the range of the reference voltages V1 and V2, the data retained in the memory cell is “01”. When the threshold voltage VTH of a memory cell falls within the range of the reference voltages V2 and V3, the data retained in the memory cell is “10”. When the threshold voltage VTH of a memory cell exceeds the reference voltage V3, the data retained in the memory cell is “11”. In the flash memory of this type, memory cell currents which vary with the threshold voltage VTH are compared with a plurality of reference currents to read data retained in the memory cells.

Four-level cell flash memories having memory cells capable of storing two bits of information can lose control of threshold voltages in write operations if defects occur among the memory cells. This means higher chances of a two-bit error in the same memory cell. Accordingly, multilevel cell flash memories of this type cannot fully relieve defects by simply performing the detection/correction of single-bit errors.

The four-level cell flash memory described above can adopt a conventional technique for detecting/correcting two-bit errors to improve the error-detection/correction efficiencies. Nevertheless, conventional circuits for detecting/correcting two-bit errors are far more complicated than those for detecting/correcting single-bit errors. Therefore, the implementation of a two-bit error detecting/correcting circuit on a flash memory has caused problems of greater chip sizes and increased fabrication costs. Moreover, a two-bit error detecting/correcting circuits have longer error-detecting/correcting times as compared with single-bit error detecting/correcting circuits. This may preclude error correction within read cycle time when four-level cell flash memories capable of high-speed reading are developed in the future.

Moreover, there has been proposed no error detection/correction technique that is tailored to a two-bit defect occurring in a single memory cell.

### SUMMARY OF THE INVENTION

An object of the present invention is to provide a multilevel cell memory capable of storing a plurality of bits of information in each single memory cell, in which reliable error detection/correction is performed by a simple method.

Another object of the present invention is to provide a multilevel cell memory capable of storing a plurality of bits of information in each single memory cell, in which error detection and error correction are achieved by a simple circuit without an increase in chip size.

According to one of the aspects of the present invention, binary bit addresses for error detection corresponding to addresses designating the individual bits of multilevel memory cells for retaining two bits of data, respectively, are assigned so that pairs of the binary bit addresses corresponding to each of the memory cells are mutually exclusive in each digit. For each digit of the binary bit addresses, first parity codes including a parity code of write data corresponding to all of the binary bit addresses having “0” in the digit and a parity code of write data corresponding to all of the binary bit addresses having “1” in the digit are generated.

When data are read from the memory cells, first parity codes of read data corresponding to the binary bit addresses whose combinations are the same as at the generation of the first parity codes of the write data are generated. That is, in reading data, first parity codes including a parity code of read data corresponding to all of the binary bit addresses having “0” in the digit and a parity code of the read data corresponding to all the binary bit addresses having “1” in the digit are generated for each digit of the binary bit addresses.

Then, the presence of a memory cell storing erroneous data in both bits is detected when the first parity codes generated in the read operation are all different from the first parity codes generated in the write operation.

The assigning of the binary bit addresses and the generation of the first parity codes are performed, for example, by a first generating circuit of the multilevel cell memory. A single memory cell having a two-bit error is detected, for example, by a first detecting circuit of the multilevel cell memory.

Simply combining the binary bit addresses to be assigned to each single memory cell so as to be mutually inverted in every bit allows the detection of a single memory cell having a two-bit error. For this reason, the first generating circuit and the first detecting circuit can be formed in a simple configuration. Therefore, reliable error detection/correction can be performed by a simple method in the multilevel cell memory capable of storing a plurality of bits of information in each single memory cell.

Since the error detection can be achieved by a simple circuit, the implementation of a circuit for detecting a two-bit error in a single memory cell causes no increase in the chip size of the multilevel cell memory.

According to another aspect of the present invention, binary cell addresses for error correction are assigned to the individual memory cells. For each digit of the binary cell addresses, a second parity code of data to be written to either of bits of the memory cells corresponding to all of the binary cell addresses having either “0” or “1” in the digit is generated. When the presence of a memory cell storing erroneous data in both bits is detected, a second parity code of data read from either of bits of the memory cells corresponding to the binary cell addresses whose combinations are same as at the generation of the second parity code of the write data is generated.

The exclusive ORs are obtained from the individual bits of the second parity code generated in the write operation and the individual bits of the second parity code generated in the read operation. The obtained exclusive ORs are assigned to respective digits of the address to determine a binary cell address having an error.

The error is corrected by inverting two bits of data read from a memory cell having the error.

The assigning of the binary cell addresses and the generation of the second parity codes are performed, for example, by a second generating circuit of the multilevel cell memory. A two-bit error occurring in a single memory cell is corrected, for example, by a first correcting circuit of the multilevel cell memory.

Since the second parity codes are generated from data corresponding to either of bits of the memory cells, the second generating circuit can be formed in a simple configuration. Therefore, a two-bit error in a single memory cell can be corrected easily by a simple circuit.

Since the error correction can be achieved by a simple circuit, the implementation of a circuit for correcting a two-bit error in a single memory cell causes no increase in the chip size of the multilevel cell memory.

According to another aspect of the present invention, the exclusive ORs are obtained from the first parity codes generated in the write operation and the first parity codes generated in the read operation. When pairs of the exclusive ORs corresponding to each of the digits concerned at the generation of the first parity codes are inverted from each other, it is detected that data read from the memory cells includes a single-bit error.

Either of the pairs of the exclusive ORs are assigned to respective digits of the address to determine a binary bit address having an error. The error is corrected by inverting data corresponding to the binary bit address among data read from the memory cells.

The detection of a single-bit error is performed, for example, by a second detecting circuit of the multilevel cell memory. The correction of a single-bit error is performed, for example, a second correcting circuit of the multilevel cell memory.

Since the first parity codes used to detect a two-bit error in a single memory cell can be utilized for the detection/correction of a single-bit error, the function of detecting/correcting a single-bit error can be added without increasing the scale of the error detection/correction circuit. That prevents an increase in the chip size of the multilevel cell memory.

According to another aspect of the multilevel cell memory having an error detection/correction function in the present invention, the semiconductor memory comprises a converting circuit for converting each bit of the first parity codes into two-bit data, and multilevel memory cells for retaining the two-bit data as the first parity codes.

According to another aspect of the multilevel cell memory having an error detection/correction function in the present invention, the semiconductor memory comprises a converting circuit for converting each bit of the second parity codes into two-bit data, and multilevel memory cells for retaining the two-bit data as the second parity codes.

Retaining the logical values (1-bit) of the first and second parity codes converted into multilevels enables a reduction in the probability of error occurrence in these parity codes. That is, the parity codes to be stored into the multilevel memory cells can be improved in reliability. As a result, the error detection/correction can be performed without fail.

### BRIEF DESCRIPTION OF THE DRAWINGS

The nature, principle, and utility of the invention will become more apparent from the following detailed description when read in conjunction with the accompanying drawings in which like parts are designated by identical reference numbers, in which:

FIG. 1 is an explanatory diagram showing a single-bit error occurring in a conventional flash memory;

FIG. 2 is an explanatory diagram showing an overview of conventional single-bit error detection/correction;

FIG. 3 is an explanatory diagram showing the relationship between logical values of data and threshold voltage VTH in a conventional flash memory that can store two bits of information in each single memory cell;

FIG. 4 is an explanatory diagram showing memory cell addressing according to the basic principles of the present invention;

FIG. 5 is an explanatory diagram showing the combinations of binary bit addresses necessary for generating first parity codes according to the basic principle of the present invention;

FIG. 6 is an explanatory diagram showing the combinations of binary cell addresses necessary for generating second parity codes according to the basic principle of the present invention;

FIG. 7 is a flowchart showing a method for error detection/correction according to the basic principles of the present invention;

FIG. 8 is a block diagram showing a first embodiment of the present invention;

FIG. 9 is an explanatory diagram showing the details of the memory cell array of FIG. 8;

FIG. 10 is an explanatory diagram showing a single-bit error occurring in the first embodiment;

FIG. 11 is an explanatory diagram showing an overview of single-bit error detection/correction using the first parity codes in the first embodiment;

FIG. 12 is an explanatory diagram showing a two-bit error occurring in a single memory cell in the first embodiment;

FIG. 13 is an explanatory diagram showing an overview of the detection of a two-bit error in a single memory cell using the first parity codes in the first embodiment;

FIG. 14 is an explanatory diagram showing an overview of two-bit error correction using the second parity codes in the first embodiment;

FIG. 15 is an explanatory diagram showing a two-bit error occurring across separate memory cells in the first embodiment;

FIG. 16 is an explanatory diagram showing an overview of the detection of a two-bit error across separate memory cells using the first parity codes in the first embodiment;

FIG. 17 is a block diagram showing a second embodiment of the present invention; and

FIG. 18 is an explanatory diagram showing the details of the spare area in the second embodiment.

### DESCRIPTION OF THE PREFERRED EMBODIMENTS

Hereinafter, the principles and embodiments of the present invention will be described with reference to the drawings.

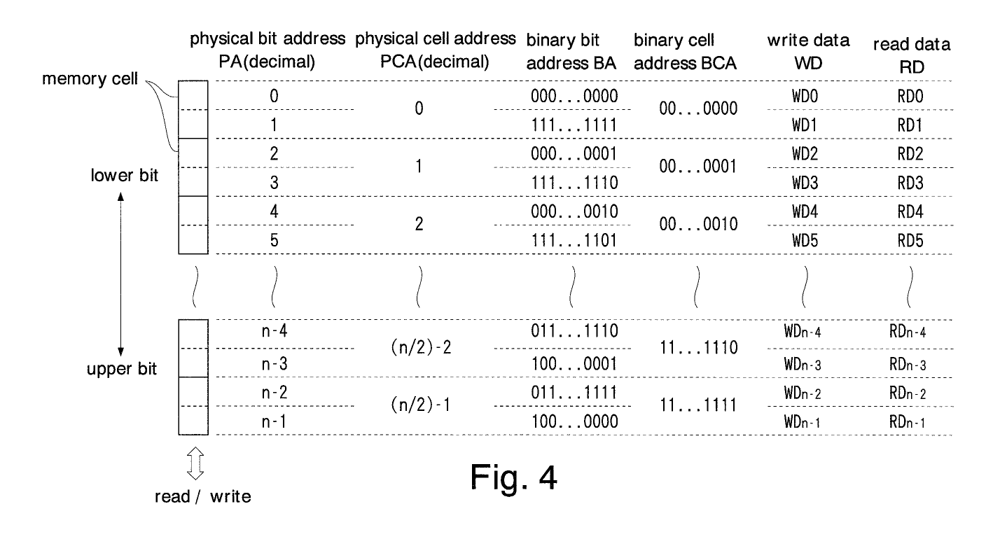

FIGS. 4-7 show the basic principles of the present invention.

A multilevel cell memory according to the present invention stores two bits of information in each single memory cell. In a single write operation, n/2 memory cells are accessed to write n bits of data. Likewise, in a single read operation, n/2 memory cells are accessed to read n bits of data. The individual bit areas to store data are identified by physical bit addresses PA of 0 to n−1. The memory cells are identified by physical cell addresses PCA of 0 to (n/2)−1.

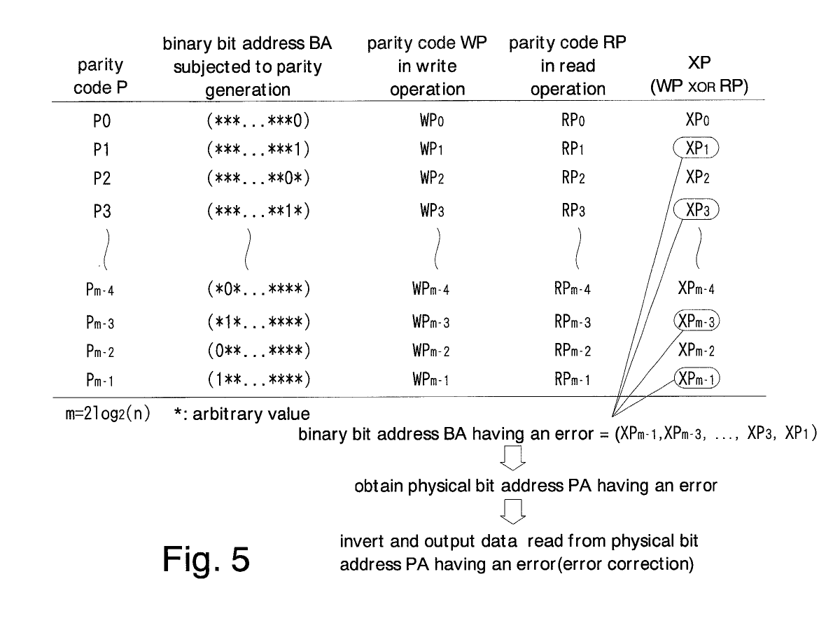

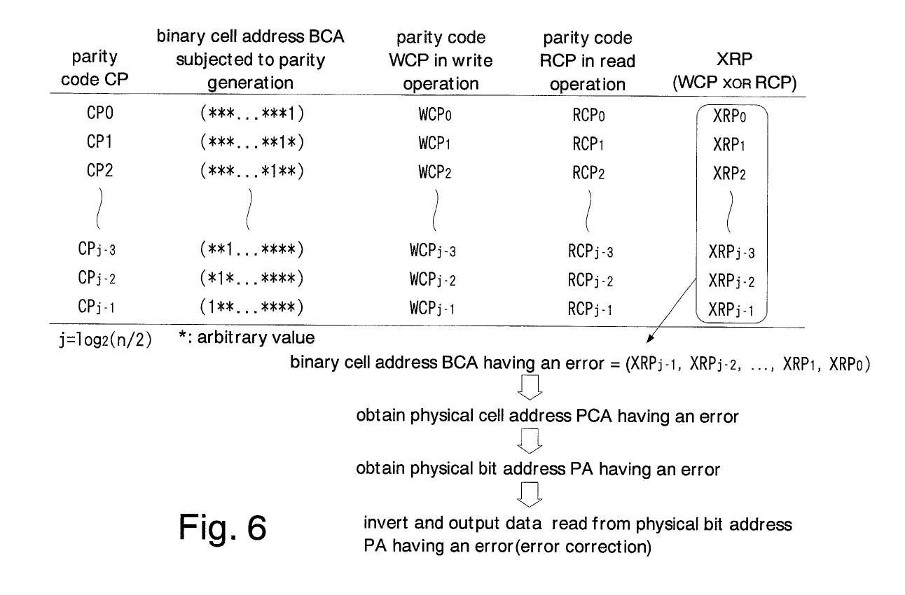

This invention uses binary bit addresses BA for generating first parity codes for error detection, and binary cell addresses BCA for generating second parity codes for error correction. The binary bit addresses BA are assigned to correspond to the addresses that designate the individual bits of the memory cells (physical bit addresses PA). The binary cell addresses BCA are assigned to correspond to the memory cells. The first parity codes and second parity codes will be described in conjunction with FIGS. 5 and 6 to be seen later.

In the present invention, a pair of binary bit addresses BA respectively corresponding to a pair of physical bit address PA that designate each memory cell are assigned so as to be exclusive of each other. This invention is therefore characterized by that the binary bit addresses BA for generating first parity codes are provided aside from the physical bit addresses PA, and every two binary bit addresses BA corresponding to a single physical address PCA are set to have a sum of “111 . . . 111” (1 in every digit).

Binary cell addresses BCA are binary representations of physical cell addresses PCA which designate individual memory cells. Write data WD0 to WDn-1 are written to memory cell areas corresponding to respective physical bit addresses PA. Read data RD0 to RDn-1 are read from these areas.

FIG. 5 shows the combinations of binary bit addresses BA necessary for generating parity codes P0 to Pm-1 for error detection (first parity code). The parity codes P0 to Pm-1 are generated from the data corresponding to these binary bit addresses BA. The number m of parity codes P0 to Pm-1 is set at twice the number of bits of a binary bit address BA (m=2·log₂ (n)).

The parity code P0 is calculated from the data corresponding to n/2 binary bit addresses BA that have “0” in their least significant digits. That is, the parity code P0 is generated from the data to be written/read under n/2 physical bit addresses PA corresponding to binary bit addresses “*** . . . ***0” (* is an arbitrary value).

The parity code P1 is calculated from the data corresponding to n/2 binary bit addresses BA that have “1” in their least significant digits. That is, the parity code P1 is generated from the data to be written/read under n/2 physical bit addresses PA corresponding to binary bit addresses “*** . . . ***1” (* is an arbitrary value).

Similarly, even-subscripted parity codes P2, P4, . . . , Pm-2 are generated from the data corresponding to n/2 binary bit addresses BA having “0” in respective predetermined digits thereof. Odd-subscripted parity codes P3, P5, . . . , Pm-1 are generated from the data corresponding to n/2 binary bit addresses BA having “1” in respective predetermined digits thereof.

Under the rules mentioned above, bits WP0 to WPm-1 of writing parity code WP (first parity code) are generated from respective predetermined n/2 bits out of the bits WD0 to WDn-1 of the n-bit write data WD shown in FIG. 4. The parity code WP is written to a predetermided memory area along with the n-bit write data WD0 to WDn-1. Similarly, bits RP0 to RPm-1 of reading parity code RP (first parity code) are generated from respective predetermined n/2 bits out of the bits RD0 to RDn-1 of n-bit read data RD. The parity code RP is generated at the time of reading n bits of data. Hereinafter, the parity codes WP and RP will be also referred to simply as parities WP and RP.

Now, description will be given of the method for error detection/correction in the present invention.

Initially, in a read operation, a parity WP is read out along with read data RD. From the bits WP0 to WPm-1 of the parity WP and the bits RP0 to RPm-1 of a parity RP that is generated from the read data RD, respective exclusive ORs XP0 to XPm-1 (WP XOR RP) are obtained. Then, the exclusive ORs XP0 to XPm-1 are used to perform error detection in the manner to be described below.

(a) When the parities WP and RP are equal in each bit, i.e., when all the bits of the exclusive OR XP are “0”, there occurs no error.

(b) When comparisons between the bits of the parities WP and RP show that either one of the parity codes P0 and P1, either one of the parity codes P2 and P3, . . . , and either one of the parities Pm-2 and Pm-1 are all inverted, there occurs a single-bit error. In other words, when the exclusive ORs of the parities WP and RP are obtained to find that all the pairs of exclusive ORs corresponding to each digit of the binary bit addresses BA concerned at generating the parities WP and RP, respectively, are inverted from each other, a single-bit error is detected. The condition for the single-bit error detection may be expressed by the following equation (1). That is, given an integer k, a single-bit error is detected when adjoining even- and odd-numbered exclusive ORs differ from each other.

(XP2k)XOR(XP2k+1)=1 (1)

(integer k=0 to ((m/2)−1), m=2·log2 (n))

Here, the error-occurring binary bit address BA (error bit address) is obtained by arranging the values of either of the pairs of exclusive ORs to respective digits of the address. In this example, the odd-subscripted exclusive ORs are arranged in descending order to obtain the value. Specifically, the digits of the error bit address are XPm-1, XPm-3, . . . , XP5, XP3, and XP1 in descending order. Then, the data read from the error bit address is inverted for error correction.

(c) If all the exclusive ORs XP0 to XPm-1 are “1”, a two-bit error occurring in a single memory cell is detected. That is, when the individual bits of the parity WP differ from the individual bits of the parity RP, a two-bit error occurring in a single memory cell is detected. The reason for this is that each pair of binary bit addresses BA corresponding to two bits to be stored into the same memory cell are combined so as to be mutually inverted in every bit.

FIG. 6 shows the combinations of binary bit addresses BCA necessary to generate parity codes CP0 to CPj-1 (second parity code) for correcting a two-bit error occurring in a single memory cell. The parity codes CP0 to CPm-1 are generated from the data corresponding to these binary bit addresses BCA. The parity codes CP0 to CPj-1 are used only to correct a two-bit error in the same memory cell (error of a single memory cell). Thus, in contrast to the generation of the parity codes P0 to Pm-1 described above, the number of parity codes CP0 to CPj-1 to be generated is small. Specifically, the number j of parity codes CP0 to CPj-1 is a half of the number of bits of a binary bit address BA (physical bit address PA), or j=log₂ (n/2). That is, the number j of parity codes CP0 to CPj-1 is the same as the number of bits of a binary cell address BCA.

The parity code CP0 is generated from either of the pairs of data corresponding to n/4 binary cell addresses BCA that have “1” in their least significant digits. That is, the parity code CP0 is generated from, for example, the pieces of data corresponding to odd-numbered physical bit addresses PA out of the pairs of physical bit addresses PA corresponding to binary cell addresses “*** . . . ***1” (* is an arbitrary value).

The parity code CP1 is generated from either of the pairs of data corresponding to n/4 binary cell addresses BCA that have “1” in their second digits. That is, the parity code CP1 is generated from, for example, the pieces of data corresponding to odd-numbered physical bit addresses PA out of the pairs of physical bit addresses PA corresponding to binary cell addresses “*** . . . **1” (* is an arbitrary value).

Similarly, the parity codes CP2 to CPj-1 are generated from either of the pairs of data corresponding to n/4 binary cell addresses BCA that have “1” in respective predetermined digits. That is, the parity codes CP0 to CPj-1 are generated from the data to be written to either of bits of the memory cells corresponding to all binary cell addresses BCA that have “0” or “1” in respective predetermined digits thereof. In this example, either of bits of the memory cells are the bits corresponding to odd-numbered physical bit addresses PA. The parity codes CP0 to CPj-1 may be generated with the bits corresponding to even-numbered physical bit addresses PA as either of the bits of the memory cells.

Parity codes WCP0 to WCPj-1 are the parity codes CP0 to CPj-1 generated in a write operation. Under the rules mentioned above, the bits WCP0 to WCPj-1 of writing parity code WCP (second parity code) are generated from respective predetermined n/4 bits out of the bits WD0 to WDn-1 of the n-bit write data WD shown in FIG. 4. The parity code WCP is written to a predetermined memory area along with the n-bit write data WD and the parity code WP mentioned above.

Similarly, parity codes RCP0 to RCPj-1 are the parity codes CP0 to CPj-1 generated in a read operation. The bits RCP0 to RCPm-1 of reading parity code RCP (second parity code) are generated from respective predetermined n/4 bits out of the bits RD0 to RDn-1 of n-bit read data RD. The parity code RCP is generated with the parity code RP, at the time of reading the read data RD. Hereinafter, the parity codes WCP and RCP will be also referred to simply as parities WCP and RCP.

Then, in a read operation, exclusive ORs XRP0 to XRPj-1 are obtained from the individual bits WCP0 to WCPj-1 of the parity WCP, read with the read data RD and the parity WP, and the individual bits RCP0 to RCPj-1 of the parity RCP, generated from the read data RD (WCP XOR RCP).

The binary cell address BCA under which the two-bit error occurs is determined by arranging the values of the exclusive ORs XRP0 to XRPj-1 to respective digits of the address. Specifically, the digits of the binary cell address BCA are XRPj-1, XRPj-2, . . . , XRP1, and XRP0 in descending order. Then, this binary cell address BCA determines the error-occurring physical cell address PCA, and the two error-occurring physical bit addresses PA. Inverting the bit data of the read data RD corresponding to these physical bit address PA corrects the two-bit error in a single memory cell.

(d) If the exclusive ORs XP0 to XPm-1 shown in FIG. 5 have a bit pattern that does not apply to any of no error, a single-bit error, or a two-bit error in a single memory cell, it follows that the occurrence of a more-than-one-bit error across two or more memory cells or the occurrence of a one-or-more-bit error in a parity-containing memory cell is detected.

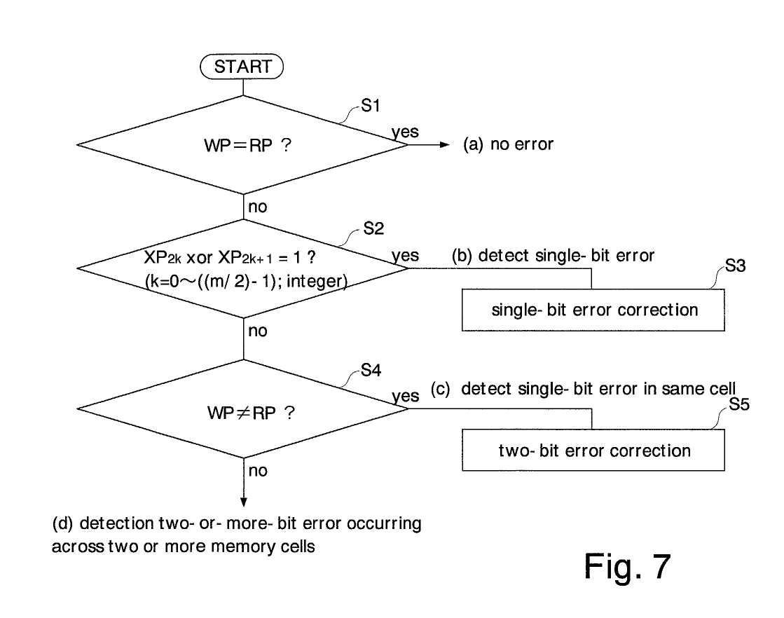

FIG. 7 shows the flow for the error detection/correction to be performed by the multilevel cell memory described above. The symbols (a) to (d) in the flow correspond to the descriptions (a) to (d) above. This flow is executed during data read operations.

Initially, at step S1, whether the write parity WP and the read parity RP are equal or not is determined. If the write parity WP and the read parity RP are equal, or all the exclusive ORs XP0 to XPm-1 shown in FIG. 5 are “0”, then a determination of no error is given. Here, the data read from the memory cells is simply output to exterior. If the write parity WP and the read parity RP are different from each other, the processing moves to step S2.

At step S2, whether or not the above-mentioned equation (1) holds for an integer k (k=0 to ((m/2)−1)) is determined. If the equation (1) holds, a single-bit error is detected so that the processing moves to step S3. If the equation (1) does not hold, the processing moves to step S4.

At step S3, single-bit error correction is performed as described in FIG. 5. That is, the data read from the memory cells is corrected for the single bit, and output to exterior.

At step S4, whether or not the write parity WP and the read parity RP are completely different from each other is determined. If the write parity WP and the read parity RP are completely different from each other, or all the exclusive ORs XP0 to XPm-1 are “1”, then a two-bit error is detected in a single memory cell so that the processing moves to step S5. If the write parity WP and the read parity RP have none of the difference patterns of steps S1, S2, and S4, then a two-or-more-bit error across two or more memory cells or a one-or-more, bit error in a parity-containing memory cell is detected.

At step S5, a two-bit error occurring in a single memory cell is corrected as described in FIG. 6. That is, the data read from the memory cells is corrected for the two bits, and output to exterior.

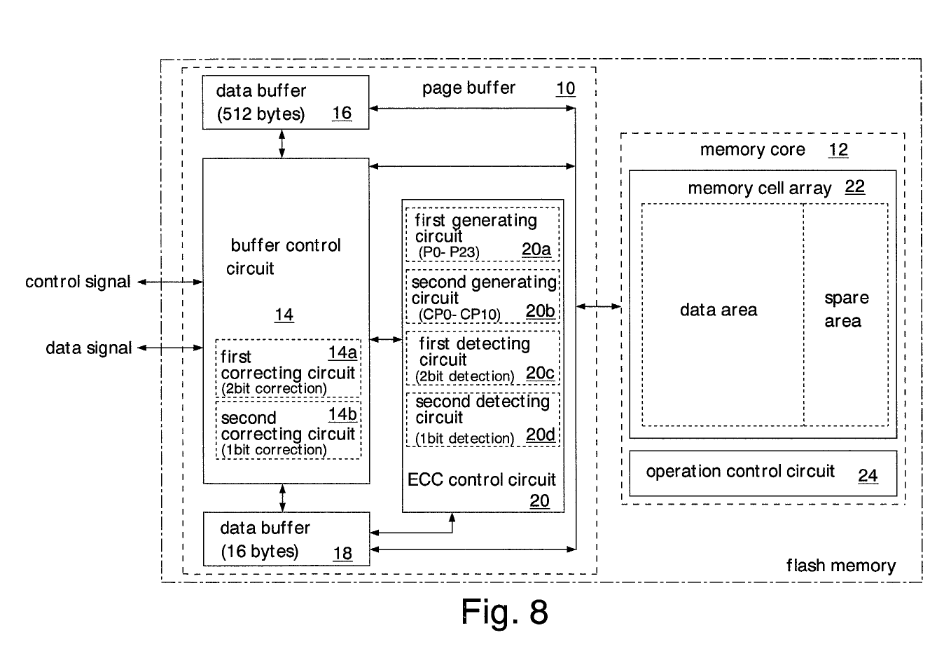

FIG. 8 shows a first embodiment of the present invention. The multilevel cell memory is formed as a floating gate type four-level cell flash memory capable of storing two bits of information in each single memory cell. In this flash memory, the amounts of carriers to be trapped in the floating gates of memory cells are adjusted in four levels according to write data. Then, four types of memory cell currents corresponding to the threshold voltages of the memory cells are detected to read two bits of data stored in the memory cells.

The flash memory has a page buffer 10 and a memory core 12, as well as not-shown input circuits, output circuits, control circuits, and the like. The page buffer 10 has a buffer control circuit 14, data buffers 16 and 18, and an FCC control circuit 20. The memory core 12 includes a memory cell array 22 which is composed of a data area and a spare area, including a plurality of pages, and an operation control circuit 24 which performs read operations, write operations (programming operations), and erase operations. Read operations and write operations are performed page by page. Erase operations are performed page by page or in steps of a plurality of pages.

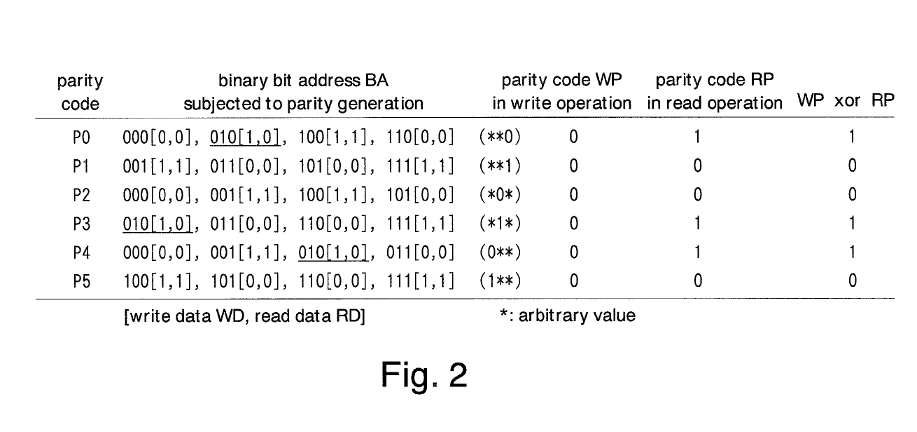

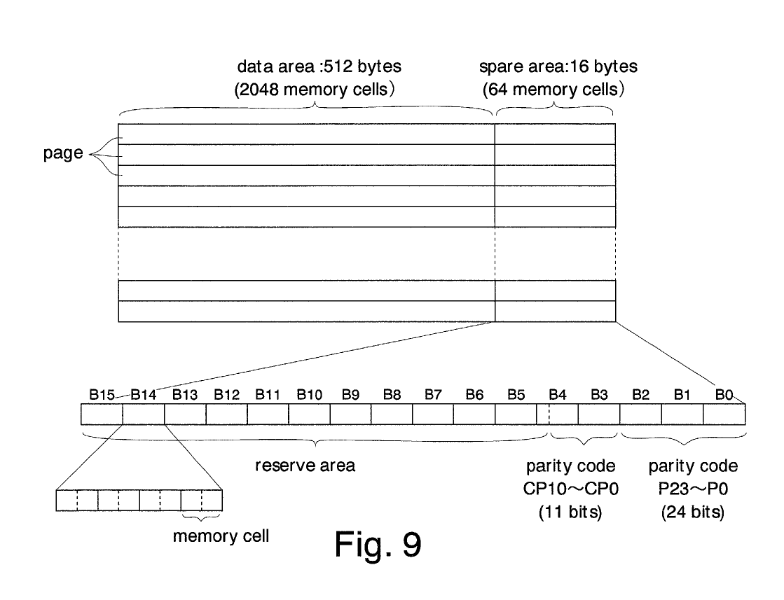

FIG. 9 shows the details of the memory cell array 22 shown in FIG. 8. Each page of the memory cell array 22 consists of 512 bytes (4096 bits=n) of data area and 16 bytes (128 bits) of spare area. Since each single memory cell can store two bits of data, a single page of data area contains 2048 memory cells. A single page of spare area contains 64 memory cells. The relationship between data to be stored into memory cells and the threshold voltage is the same as that of FIG. 2 described above. That is, the memory cells have four types of threshold voltages divided by the reference voltages V1, V2, and V3. Logical data of “00”, “01,”, “10”, and “11” are assigned to the threshold voltages in ascending order.

In each page of spare area, the lower 35 bits are allocated to an area for storing 24 bits of parity code P0-P23 (first parity code) and 11 bits of parity code CP0-CP10 (second parity code). The remainder of the spare area are allocated for reserve areas.

The buffer control circuit 14 shown in FIG. 8 has a first correcting circuit 14a for correcting a two-bit error occurring in a single memory cell on the basis of the parities CP0-CP10, and a second correcting circuit 14b for correcting a single-bit error on the basis of the parities P0-P23. The buffer control circuit 14 controls the data buffers 16, 18 and the ECC control circuit 20 in accordance with control signals from exterior.

The data buffer 16 is a buffer for reading/writing data signals from/to predetermined pages of data area in the memory cell array 22, with a capacity of 512 bytes. In this flash memory, a data signal consists of eight bits. Therefore, a single byte of data signal is input 512 times to input 512 bytes of data signals to the data buffer 16. The data buffer 18 is a buffer for reading/writing data signals from/to predetermined pages of spare area in the memory cell array 22, with a capacity of 16 bytes.

The ECC control circuit 20 has a first generating circuit 20a for generating the parities P0-P23, a second generating circuit for generating the parities CP0-CP10, a first detecting circuit 20c for detecting a two-bit error occurring in a single memory cell on the basis of the parities CP0-CP10, and a second detecting circuit 20d for detecting a single-bit error on the basis of the parities P0-P23. The ECC control circuit 20 performs the generation of the parity codes and the detection of errors described in FIGS. 4-7.

In write operations, the buffer control circuit 14 writes 512 bytes of write data (data signals) successively supplied from exterior, into specified pages in the data area through the data buffer 16. Here, the first generating circuit 20a and the second generating circuit 20b in the ECC control circuit 20 generate parities WP0-WP23 and parities WCP0-WCP10, respectively, from write data transferred from the buffer control circuit 14, and output the generated parities to the data buffer 18. The buffer control circuit 14 writes the parities WP0-WP23 and WCP0-WCP10, transferred to the data buffer, into specified pages in the spare area.

In read operations, the buffer control circuit 14 reads data and parity codes from specified pages of the data area and spare area, respectively, and temporarily holds the same in the data buffers 16 and 1 8, respectively. Here, the first generating circuit 20a and the second generating circuit 20b in the ECC control circuit 20 generate parities RP0-RP23 and parities RCP0-RCP10, respectively, from the 512 bytes of data read from the data area.

The first detecting circuit 20c and the second detecting circuit 20d of the ECC control circuit 20 calculate the exclusive ORs XP0-XP23 of the parities WP0-WP23 read from the spare area and the parities RP0-RP23 generated by the first generating circuit 20a. As has been discussed in the basic principles above, the exclusive ORs XP0-XP23 are used to detect no error, a single-bit error, a two-bit error occurring in a single memory cell, a two-or-more-bit error occurring across two or more memory cells, or a one-or-more-bit error in a parity-containing memory cell. Incidentally, the first detecting circuit 20c and the second detecting circuit 20d may be composed of the same circuit.

If no error is detected, the ECC control circuit 20 informs the buffer control circuit 14 of the detection of no error. The buffer control circuit 14 simply outputs the 512 bytes of read data held in the buffer 16 to exterior.

If a single-bit error is detected by the second detecting circuit 20d, the ECC control circuit 20 transmits the error-occurring physical bit address PA (error bit address) to the buffer control circuit 14. The second correcting circuit 14b in the buffer control circuit 14 inverts the data corresponding to the error bit address among the 512 bytes of read data held in the buffer 16. Then, the error-corrected, 512 bytes of read data are output to exterior.

If a two-bit error occurring in a single memory cell is detected, the first detecting circuit 20c calculates the error-occurring binary cell address BCA (binary cell address having an error) from the parities RCP0-RCP10 as described in FIG. 6. The first detecting circuit 20c determines two consecutive physical bit addresses PA (error bit addresses) from the binary cell address BCA calculated, and transmits the physical bit addresses PA calculated to the buffer control circuit 14. The first correcting circuit 14a in the buffer control circuit 14 inverts the data corresponding to the error bit addresses among the 512 bytes of read data held in the buffer 16. Then, the error-corrected, 512 bytes of read data are output to exterior.

If a two-or-more-bit error occurring across two or more memory cells, or a one-or-more-bit error in a parity-containing memory cell is detected, the ECC control circuit 20 informs the buffer control circuit 14 of the occurrence of an uncorrectable error. The buffer control circuit 14 outputs the occurrence of an uncorrectable error to exterior in the form of a control signal. Then, for example, the system implementing the flash memory subsequently quits using the error-occurring page, or retries the read operation to the same page.

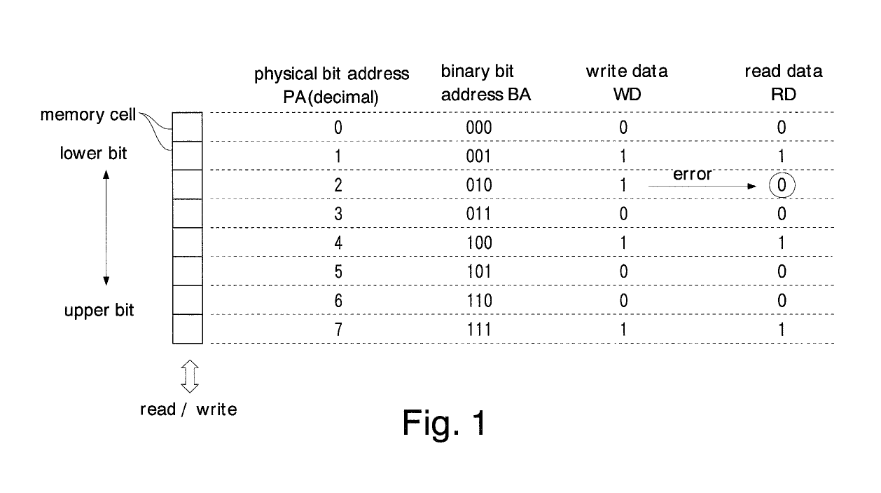

Next, the correction/detection of a single-bit error, the correction/detection of a two-bit error occurring in a single memory cell, and the detection of a two-or-more-bit error occurring across two or more memory cells (or a one-or-more-bit error in a parity-containing memory cell) mentioned above will be described in specific figures. For simplicity, the following description deals with the case of accessing (writing/reading) memory cells in steps of eight bits as in FIG. 1 described above. In this example, odd parity codes are used.

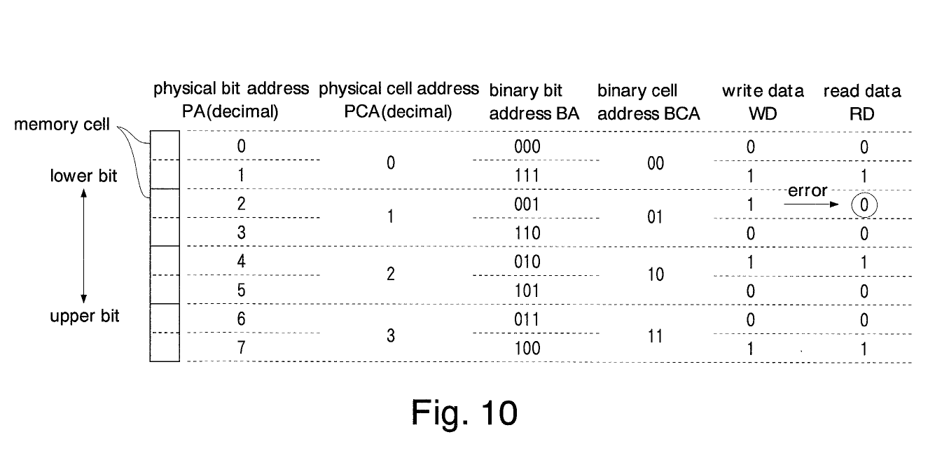

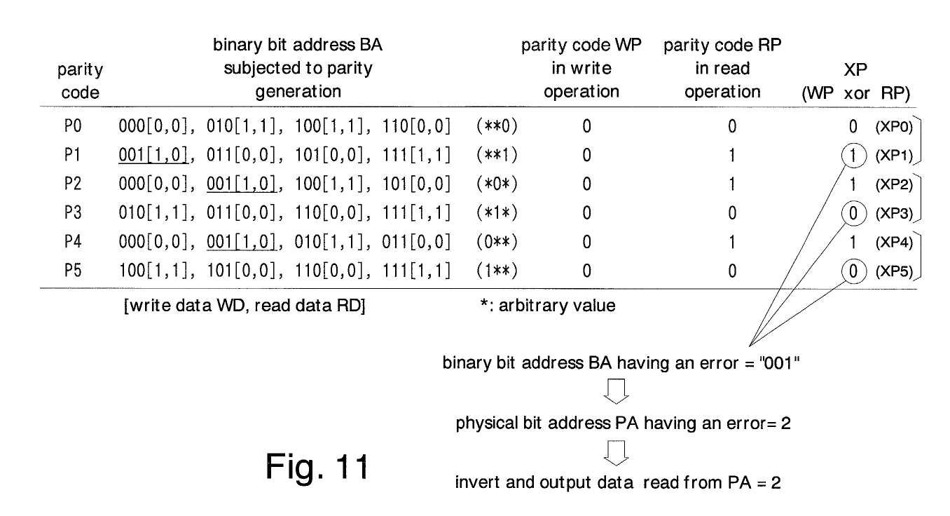

FIGS. 10 and 11 show the method for detecting and correcting a single-bit error. As in FIG. 1, write data WD of “10010110” in binary is written to memory cells, and read data RD of “10010010” in binary is read from the memory cells. That is, a single-bit error occurs in the memory cell having a physical bit address PA of “2”.

As shown in FIG. 11, the first generating circuit 20a shown in FIG. 8 initially generates parity codes P0-P5 from data corresponding to binary bit addresses BA having “0” or “1” in respective digits. The second detecting circuit 20d obtains the exclusive ORs of the even-subscripted exclusive ORs ((P0, for example) and the adjoining odd-subscripted exclusive ORs (XP1, for example), respectively. A single-bit error is detected on the basis that all of these exclusive ORs are “1”. The second detecting circuit 20d obtains the error-occurring binary bit address BA (“001”) from the odd-subscripted parity codes XP5, XP3, and XP1. Besides, from the binary bit address BA obtained, the second detecting circuit 20d determines the physical bit address PA (“2”) under which the single-bit error occurs. After this, the second correcting circuit 14b in the buffer control circuit 14 inverts the data read from the physical bit address PA. That is, the single-bit error is corrected.

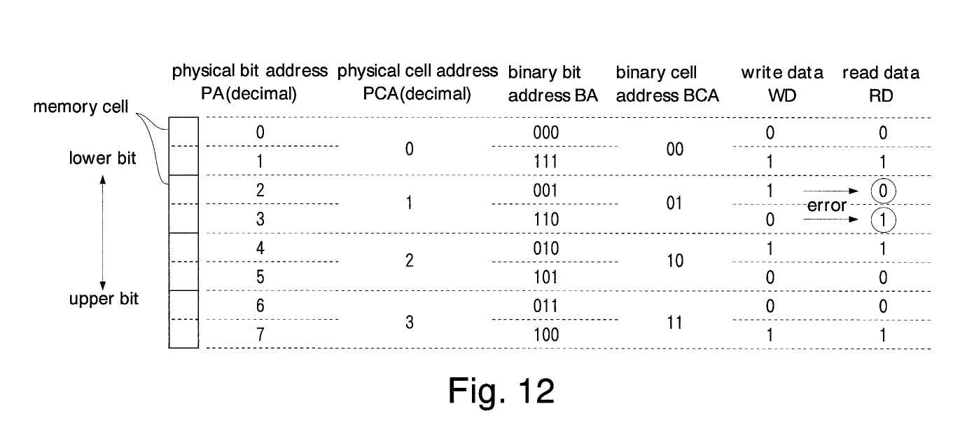

FIGS. 12-14 show the method for detecting and correcting a two-bit error occurring in a single memory cell. In this example, write data WD of “10010110” in binary is written to memory cells, and read data RD of “10011010” in binary is read from the memory cells. That is, a two-bit error occurs in the memory cell having physical bit addresses PA of “2” and “3” (physical cell address PCA=“1”).

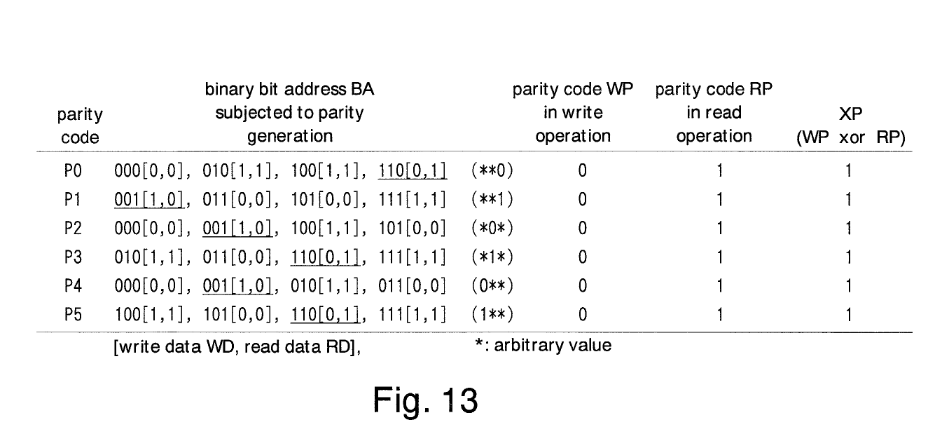

As shown in FIG. 13, the first generating circuit 20a shown in FIG. 8 initially generates the parity codes P0-P5 from data corresponding to binary bit addresses BA having “0” or “1” in respective digits. The first detecting circuit 20c detects a two-bit error occurring in a single memory cell on the basis that all the exclusive ORs XP are “1”.

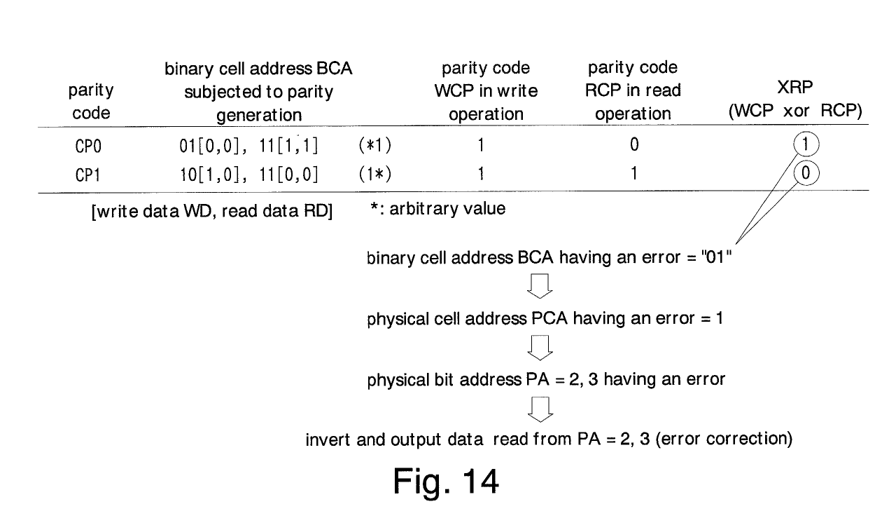

Next, as shown in FIG. 14, the second detecting circuit 20d obtains the error-occurring binary cell address BCA (“01”) from the exclusive ORs XRP which are obtained from the parity codes WCP and RCP. Moreover, from the binary bit address BCA obtained, the second detecting circuit 20d determines the physical cell address PCA (=“1”) and the physical bit addresses PA (=“2”, “3”). After this, the first correcting circuit 14a of the buffer control circuit 14 shown in FIG. 8 inverts the data read from the physical bit addresses PA. That is, the two-bit error occurring in a single memory cell is corrected.

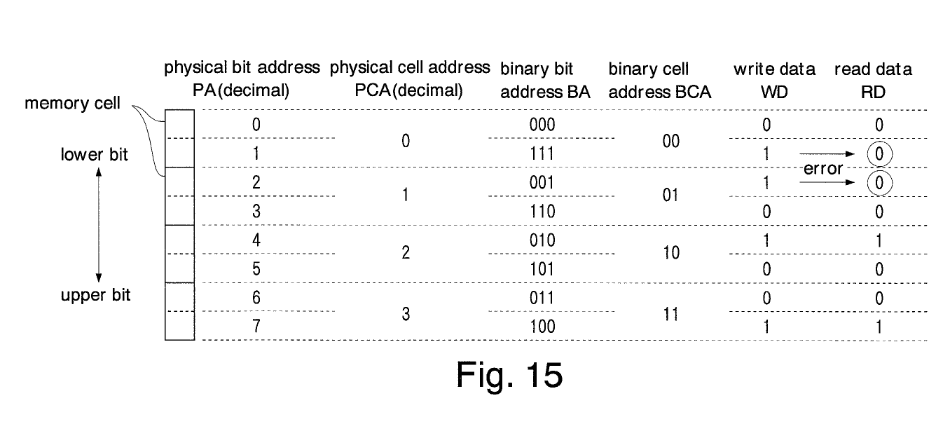

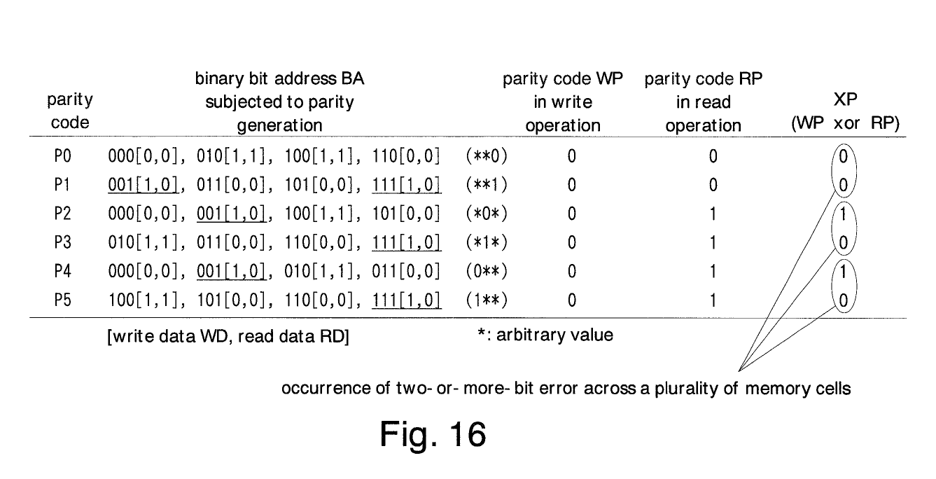

FIGS. 15 and 16 show the method of detecting a two-or-more-bit error occurring across two or more memory cells, or a one-or-more-bit error in a parity-containing memory cell. In this example, write data WD of “10010110” in binary is written to memory cells, and read data RD of “10010000” in binary is read from the memory cells. That is, a two-bit error occurs across the memory cells having physical bit addresses PA of “1” and “2” (a two-bit error across the physical cell addresses PCA of “0” and “1”).

As shown in FIG. 16, the first generating circuit 20a initially generates the parity codes P0-P5 from data corresponding to binary bit addresses BA having “0” or “1” in respective digits. The ECC control circuit 20 detects a two-or-more-bit error occurring across two or more memory cells or a one-or-more-bit error in a parity-containing memory cell, on the basis that the exclusive ORs XP have none of the patterns expected in advance.

As has been described, in the present embodiment, binary bit addresses BA are assigned to each memory cell in such a combination that they are mutually inverted in every bit. As a result, a two-bit error occurring in a single memory cell can be easily detected by the first generating circuit 20a and first detecting circuit 20c of simple configuration. Therefore, the four-level cell semiconductor memory can perform reliable error detection/correction by a simple method.

Since the parity codes CP0-CP10 are generated from the data corresponding to either of bits of the memory cells, the second generating circuit 20b can be formed in a simple configuration. That is, a two-bit error in a single memory cell can be corrected by a simple circuit. Since the first and second detecting circuits 20c and 20d of simple configuration can correct errors, the four-level cell flash memory is prevented from increasing in chip size.

The detection/correction of a single-bit error is performed by utilizing the parity codes P0-P23 which are used to detect a two-bit error in a single memory cell. Therefore, the function of detecting/correcting a single-bit error can be added without increasing the scale of the error detecting/correcting circuit. That is, the multilevel cell memory is prevented from an increase in chip size.

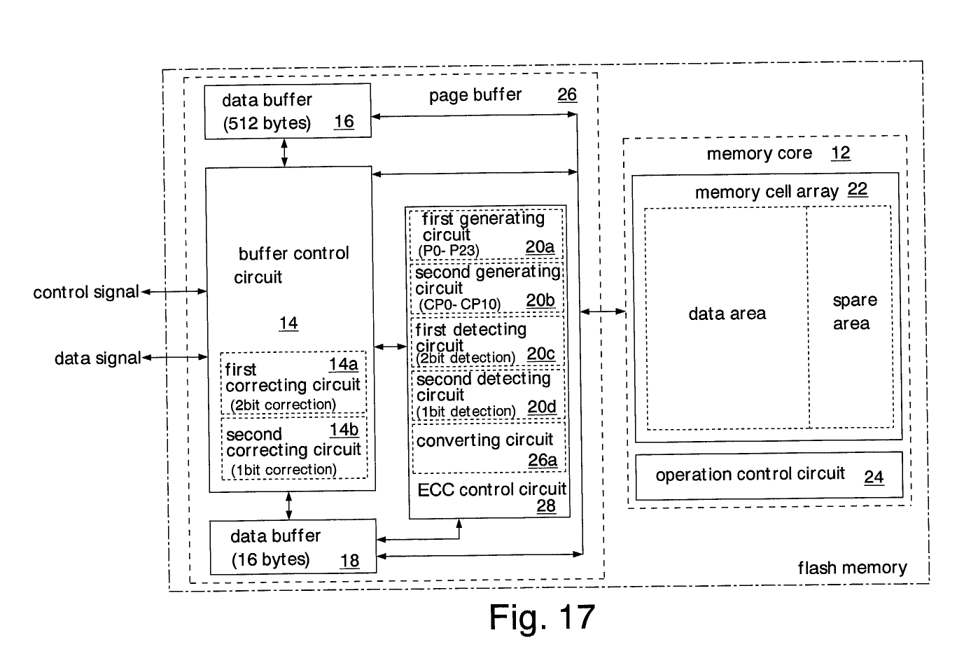

FIG. 17 shows a second embodiment of the multilevel cell memory in the present invention. The same elements as those described in the first embodiment will be designated by identical reference numbers. Detailed description thereof will be omitted.

The multilevel cell memory in this embodiment is formed as a floating gate type flash memory capable of storing two bits of information in each single memory cell. The flash memory includes a page buffer 26 having an ECC control circuit 28, instead of the page buffer of the first embodiment having the ECC control circuit 20. The ECC control circuit 28 contains a converting circuit 26a, aside from the same first generating circuit 20a, second generating circuit 20b, first detecting circuit 20c, and second detecting circuit 20d as those of the first embodiment. The other circuits of the page buffer 26 and the memory core 12 have the same configurations as those of the first embodiment.

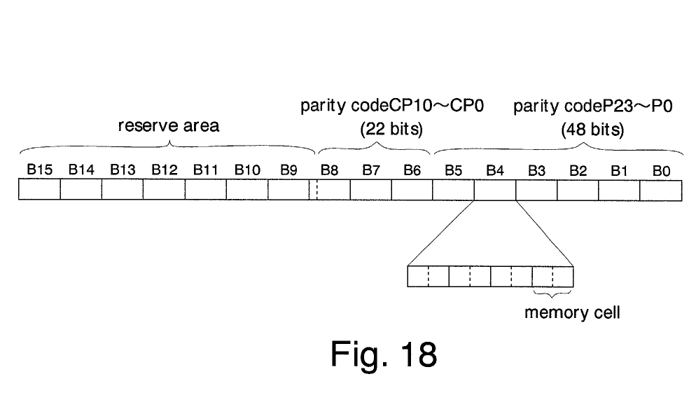

FIG. 18 shows the details of the spare area in the memory cell array 22 shown in FIG. 17. This embodiment uses 481 bits and 22 bits of spare areas to store 24 bits of parity code WP0-WP23 and 11 bits of parity code WCP0-WCP10, respectively.

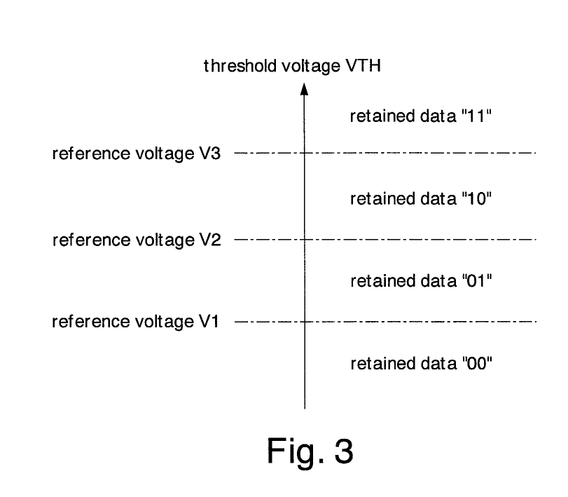

For example, given that the relationship between data to be stored in memory cells and the threshold voltage is the same as in FIG. 3 described above, the converting circuit 26a shown in FIG. 17 converts logical values of parity codes of “0” and “1” into logical values of “00” and “11”, respectively. That is, the converting circuit 26a converts the logical value of a parity code from a single bit to two bits. In this way, the logical values of parity codes can be converted into the logical values corresponding to the extreme threshold voltages shown in FIG. 3, to lower the probability of occurrence of parity code errors. That is, these parity codes to be stored into the spare areas improve in reliability.

This embodiment can offer the same effects as those obtained from the first embodiment described above. Besides, in this embodiment, each bit of the parity codes WP0 to WPm-1 and parity codes WCP0 to WCPJ-1 is stored by using two bits of memory cell. This allows an improvement in the reliability of the parity codes. Consequently, the error detection and error correction can be performed without fault.

Note that the embodiments described above have dealt with the cases where logical data of “00”, “01”, “10”, and “11” are assigned in the ascending order of the threshold voltages in the memory cells. However, the present invention is not limited to such embodiments. For example, logical data of “00”, “01”, “11”, and “10” may be assigned in the ascending order of the threshold values. In this case, two-bit errors will not occur even if the value of the threshold voltage of a memory cell changes to that of an adjoining area. This allows a reduction in the probability of occurrence of two-bit errors.

The embodiments described above have dealt with the cases where odd parities are used for error detection/correction. However, the present invention is not limited to such embodiments. For example, the error detection/correction may be performed by using even parities.

The above-described embodiments have dealt with the cases where the present invention is applied to a multilevel cell flash memory. However, the present invention is not limited to such embodiments. For example, the present invention may be applied to multilevel cell ferroelectric memories. Moreover, the present invention may be applied to other non-volatile semiconductor memories and volatile semiconductor memories which can store more than one bit.

The first embodiment described above has dealt with the case where the parity codes CP0-CP10 are generated from sets of binary cell addresses BCA that have “1” in respective digits. However, the present invention is not limited to such an embodiment. For example, the parity codes CP0-CP10 may be generated from sets of binary cell addresses BCA that have “0” in respective digits.

The invention is not limited to the above embodiments and various modifications maybe made without departing from the spirit and the scope of the invention. Any improvement may be made in part or all of the components.

What is claimed is:

1. A method for error detection/correction of a multilevel cell memory having memory cells each for retaining two bits of data, the method comprising the steps of:
assigning binary bit addresses for error detection corresponding to addresses designating individual bits of said memory cells, respectively, so that pairs of said binary bit addresses corresponding to each of said memory cells are mutually exclusive in each digit;
generating, for each digit of said binary bit addresses, first parity codes including a parity code of write data corresponding to all of said binary bit addresses having “0” in said digit and a parity code of said write data corresponding to all of said binary bit addresses having “1” in said digit;
generating first parity codes of read data corresponding to said binary bit addresses whose combinations are the same as at the generation of said first parity codes of said write data, when reading data from said memory cells; and
detecting a presence of one memory cell storing erroneous data in both bits when said first parity codes generated in the read operation are all different from said first parity codes generated in the write operation.

2. The method for error detection/correction of a multilevel cell memory according to claim 1, comprising the steps of:
assigning binary cell addresses for error correction to said individual memory cells;
generating, for each digit of said binary cell addresses, a second parity code of data to be written to either of bits of said memory cells corresponding to all of said binary cell addresses having either “0” or “1” in said digit;
generating a second parity code of data read from said either of bits of said memory cells corresponding to said binary cell addresses whose combinations are the same as at the generation of said second parity code of said write data when a presence of one memory cell storing erroneous data in both bits is detected;
obtaining exclusive ORs of individual bits of said second parity code generated in said write operation and individual bits of said second parity code generated in said read operation;
determining a binary cell address having an error by assigning the obtained exclusive ORs to respective digits of the address; and
correcting the error by inverting two bits of data read from said memory cell having the error.

3. The method for error detection/correction of a multilevel cell memory according to claim 1, comprising the steps of:
obtaining exclusive ORs of said first parity codes generated in said write operation and said first parity codes generated in said read operation;
detecting that data read from said memory cells includes a single-bit error when pairs of said exclusive ORs corresponding to each of said digits concerned at the generation of said first parity codes are all inverted from each other;
determining a binary bit address having an error by assigning either of said pairs of exclusive ORs to respective digits of the address; and
correcting the error by inverting data corresponding to the determined binary bit address among said data read from said memory cells.

4. A multilevel cell memory having an error detection/correction function, comprising:
a plurality of memory cells each for retaining two bits of data;
a first generating circuit for
assigning binary bit addresses for error detection corresponding to addresses designating individual bits of said memory cells, respectively, so that pairs of said binary bit addresses corresponding to each of said memory cells are mutually exclusive in each digit,
generating, for each digit of said binary bit addresses, first parity codes including a parity code of write data corresponding to all of said binary bit addresses having “0” in said digit and a parity code of said write data corresponding to all of said binary bit addresses having “1” in said digit, and
generating first parity codes of read data corresponding to said binary bit addresses whose combinations are the same as at the generation of said first parity codes of said write data, when reading data from said memory cells; and
a first detecting circuit for detecting a presence of one memory cell storing erroneous data in both bits when said first parity codes generated in the read operation are all different from said first parity codes generated in the write operation.

5. The multilevel cell memory having an error detection/correction function according to claim 4, comprising:
a converting circuit for converting each bit of said first parity codes into two-bit data; and
multilevel memory cells each for retaining said two-bit data as said first parity codes.

6. The multilevel cell memory having an error detection/correction function according to claim 4, comprising:
a second generating circuit for
assigning binary cell addresses for error correction to said individual memory cells,
generating, for each digit of said binary cell addresses, a second parity code of data to be written to either of bits of said memory cells corresponding to all of said binary cell addresses having either “0” or “1” in said digit, and
generating a second parity code of data read from said either of bits of said memory cells corresponding to said binary cell addresses whose combinations are the same as at the generation of said second parity code of said write data when a presence of one memory cell storing erroneous data in both bits is detected; and
a first correcting circuit for obtaining exclusive ORs of individual bits of said second parity code generated in said write operation and individual bits of said second parity code generated in said read operation,
determining a binary cell address having an error by assigning the obtained exclusive ORs to respective digits of the address, and
correcting the error by inverting two bits of data read from said memory cell having the error.

7. The multilevel cell memory having an error detection/correction function according to claim 6, comprising:
a converting circuit for converting each bit of said second parity codes into two-bit data; and
multilevel memory cells each for retaining said two-bit data as said second parity codes.

8. The multilevel cell memory having an error detection/correction function according to claim 4, comprising:
a second detecting circuit for
obtaining exclusive ORs of said first parity codes generated in said write operation and said first parity codes generated in said read operation, and
detecting that data read from said memory cells includes a single-bit error when pairs of said exclusive ORs corresponding to said digits concerned at the generation of said first parity codes are all inverted from each other; and a second correcting circuit for
determining a binary bit address having an error by assigning either of said pairs of exclusive ORs to respective digits of the address, and
correcting the error by inverting data corresponding to the determined binary bit address among said data read from said memory cells.
